(19) United States
(12) Patent Application Publication
(10) Pub. No.: US 2026/0122960 A1
(43) Pub. Date: Apr. 30, 2026

(54) POWER SEMICONDUCTOR DEVICE AND METHOD FOR PRODUCING A POWER SEMICONDUCTOR DEVICE

(71) Applicant: Hitachi Energy Ltd, Zürich (CH)

(72) Inventors: Andrei MIHAILA, Rieden (CH); Gianpaolo ROMANO, Baden (CH); Lars KNOLL, Hägglingen (CH); Nazareno DONATO, Norwich, Sprowston (GB); Florin UDREA, Cambridge, Cambridgeshire (GB)

(21) Appl. No.: 19/150,486

(22) PCT Filed: Jan. 31, 2023
(86) PCT No.: PCT/EP2023/052303

§ 371 Date: Jul. 23, 2025

(51) Int. Cl. H10D 30/65; H10D 30/01; H10D 62/10; H10D 62/60

(52) U.S. Cl. CPC H10D 30/65; H10D 30/0281; H10D 62/126; H10D 62/60

(57) ABSTRACT

A power semiconductor device comprising a drift layer of a first conductivity type, at least one well region of a second conductivity type being different from the first conductivity type, and at least one first doped region of the first conductivity type and at least one second doped region of the second conductivity type, wherein the at least one well region, the at least one first doped region and the at least one second doped region are provided at a first side of the power semiconductor device, the at least one first doped region and the at least one second doped region are spaced apart from the drift layer by the at least one well region, and an interface between the at least one first doped region and the at least one second doped region is structured.

The present disclosure relates to a power semiconductor device and a method for producing a power semiconductor device.

A power semiconductor device is realized e.g. as a metal-oxide-semiconductor field-effect transistor, MOSFET. The MOSFET may be based on a wide band-gap material such as e.g. silicon carbide, SiC, material. 650V and 1200V-rated SiC MOSFETs are currently commercially available. Implemented with either planar or trench cell designs, SiC MOSFETS provide competitive static losses, fast dynamic performance and adequate reliability. Regarding the fault handling capability, SiC MOSFETs still fall short of the typical industry standard values shown by their Si counterparts. This is typically associated with the strong trade-off between conduction losses and short-circuit withstand time, SCWT.

Embodiments of the disclosure relate to a power semiconductor device, which has an improved efficiency. A further embodiment relates to a method for producing such a power semiconductor device.

This is achieved by the subject matter of the independent claims. Further embodiments are evident from the dependent claims and the following description.

The term “power” here and in the following, for example, refers to power semiconductor devices adapted for processing voltages and currents more than 100 V, e.g. 650 V or 1200V and/or more than 1 A.

The power semiconductor device is, for example, a power metal insulating semiconductor field-effect transistor, power MISFET for short. The term MISFET shall also comprise MOSFETs, which have an oxide as insulating material at the gate. The power semiconductor device may also be an insulated-gate bipolar transistor, IGBT.

Exemplarily the power MISFET comprises a wide bandgap material, which can be silicon carbide, SiC. Thus, the power semiconductor device is exemplarily embodied as a power SiC MISFET, in particular a power SiC MOSFET.

According to an embodiment, the power semiconductor device comprises a drift layer of a first conductivity type. For example, the drift layer comprises a semiconductor material or consists of a semiconductor material. Exemplarily the semiconductor material is SiC. For example, the drift layer comprises first dopants, which define the first conductivity type.

The drift layer has, for example, a main extension plane. For example, lateral directions are aligned parallel to the main extension plane and a vertical direction is aligned perpendicular to the main extension plane.

According to the embodiment, the power semiconductor device comprises at least one well region of a second conductivity type being different from the first conductivity type.

Exemplarily, the power semiconductor device comprises a plurality of well regions, in particular at least two well regions. The two well regions are exemplarily separated from one another in lateral directions.

For example, the well region, in particular all well regions, extends along a main extension direction in lateral directions. The main extension directions of the well regions can be aligned parallel to one another.

The well region comprises or consists of a semiconductor material, which is, for example, the same material as the semiconductor material of the drift layer. Exemplarily, the well region comprises second dopants, which define the second conductivity type.

Exemplarily, the first dopants are n-type dopants such that the first conductivity type is an n-type conductivity and the second dopants are p-type dopants such that the second conductivity type is a p-type conductivity, or vice versa. For example, the n-type conductivity is achieved by using phosphorus (P) and/or nitrogen (N) as the first dopants. The p-type conductivity is achieved by using aluminium (Al) and/or boron (B) as the second dopants.

According to the embodiment, the power semiconductor device comprises at least one first doped region of the first conductivity type and at least one second doped region of the second conductivity type.

The first doped region and the second doped region comprise or consist of a semiconductor material, which is, for example, the same material as the semiconductor material of the drift layer. Exemplarily, the first doped region comprises further first dopants. Exemplarily, the second doped region comprises further second dopants. For example, the further first dopants are n-type dopants and the further second dopants are p-type dopants, or vice versa.

Exemplarily, the further first dopants are the same dopants as the first dopants. Further, the further second dopants are exemplarily the same dopants as the second dopants.

Exemplarily, the drift layer has a homogeneous doping concentration so that a maximum doping concentration corresponds to a mean doping concentration. For example, a maximum doping concentration of the first doped region is higher than the maximum doping concentration of the drift layer. Exemplarily, the maximum doping concentration of the first doped region is at least one or at least two orders of magnitude higher than the maximum doping concentration of the drift layer. For example, the maximum doping concentration of the drift layer is at least 1·10¹⁴ cm⁻³ and at most 1·10¹⁷ cm⁻³.

For example, a maximum doping concentration of the second doped region is higher than a maximum doping concentration of the well region. Exemplary, the maximum doping concentration of the second doped region is at least one or two orders of magnitude higher than the maximum doping concentration of the well region.

For example, the maximum doping concentration of the first doped region is at least 1·10¹⁶ cm⁻³ and at most 1·10²¹ cm⁻³. For example, the maximum doping concentration of the second doped region is at least 1·10¹⁷ cm⁻³ and at most 1·10²¹ cm⁻³.

In particular, at least a part of the first doped region form a source region of the power semiconductor device. The source region is an area, where charge carriers, e.g. electrons or holes, are injected into the well region.

According to the embodiment of the power semiconductor device, the at least one well region, the at least one first doped region and the at least one second doped region are provided at a first side of the power semiconductor device.

The at least one well region, the at least one first doped region and the at least one second doped region each extend in vertical direction from the first side up to a predetermined depth. The well region can have a first depth, the first doped region can have a second depth and the second doped region can have a third depth.

Exemplary, the first depth is larger than the second depth and the third depth. For example, the third depth is larger than the second depth or alternatively, the second depth and the third depth are equal. For example, the second depth is at least 0.1 μm and at most 0.5 μm. For example, the third depth is at least 0.3 μm and at most 3 μm.

For example, a first main surface at the first side of the power semiconductor device is formed flat. The first main surface extends parallel to the lateral directions. This is to say that a top surface of the well region, a top surface of the first doped region and a top surface of the second doped region are part of the first main surface.

According to the embodiment of the power semiconductor device, the at least one first doped region and the at least one second doped region are spaced apart from the drift layer by the at least one well region.

The first doped region and the second doped region are exemplarily embedded in the well region. This is to say that outer surfaces of the first doped region and the second doped region are covered by the well region, except the top surfaces of the first doped region and the second doped region. Exemplarily, the top surface of the first doped region, the top surface of the second doped region and the top surface of the well region terminate flush with one another.

For example, the top surfaces of the first doped region and the second doped region are at least in regions externally contactable in an electrical conductive manner.

Each well region is, exemplarily, provided with two first doped regions and one second doped region. The second doped region is arranged in lateral directions between the two first doped regions.

According to the embodiment of the power semiconductor device, an interface between the at least one first doped region and the at least one second doped region is structured being non uniform in a main extension direction of the at least one well region. For example, the first doped region and the second doped region are directly adjacent to one another in lateral directions. This is that the first doped region and the second doped region form an interface.

Exemplarily, an interface being non-structured extends uniformly along the main extension direction of the well region. The interface being structured is in particular not a flat interface. In fact a non-structured interface is characteristic for the flat interface. Exemplarily, the interface being structured comprises structures formed by an extent in lateral directions of the first doped region and thus formed by an extent in lateral directions of the second doped region. In this context, the structures have an extension being larger than irregularities resulting from production tolerances. For example, the non uniform structure comprise a stepped structure. This is the non uniform structure is in particular not a continuous rectilinear structure.

With such a structured interface between the first doped region and the second doped region, on resistance values, Rₒₙ, experience only a small increase of about at most 7% to at most 8% in comparison to regions without a structured interface. Further, in such a structured interface, a maximal saturation current of the drain, I_{Dsat_max}, decreases by at least 40% as compared to conventional MOSFET values. As I_{Dsat_max} is directly related to the SCWT, this means that a MOSFET with a structured interface offers advantageously a considerably improved conduction losses to SCWT trade-off.

This is to say that the power semiconductor device with the interface being structured, results advantageously in longer SCWT values and, hence, improved device ruggedness.

According to a further embodiment of the power semiconductor device, the at least one second doped region comprises a plurality of parts. Exemplarily, all the parts can have a maximum doping concentration and/or a distribution of the second dopants being equal to one another. Alternatively, at least some of the parts can have a maximum doping concentration and/or a distribution of the second dopants being different to one another.

According to a further embodiment of the power semiconductor device, the plurality of parts are arranged consecutively along a main extension direction next to one another. The main extension direction extends in particular along the main extension direction of the respective well region.

According to a further embodiment of the power semiconductor device, each of the plurality of parts have a length perpendicular to the main extension direction. Exemplarily, the lengths of all the parts can be equal to one another. Alternatively, the lengths of at least some of the parts can be different to one another.

According to a further embodiment of the power semiconductor device, directly neighbouring parts are in direct contact to one another along the main extension direction.

According to a further embodiment of the power semiconductor device, directly neighbouring parts are spaced apart from one another along the main extension direction. In this embodiment, the first doped region is arranged in lateral directions between directly neighbouring parts. This is that the parts are spaced apart in lateral directions by the first doped region.

According to a further embodiment of the power semiconductor device, the plurality of parts comprises first parts and second parts being arranged consecutively alternating along the main extension direction.

According to a further embodiment of the power semiconductor device, each first part has a first length perpendicular to the main extension direction and each second part has a second length perpendicular to the main extension direction.

According to a further embodiment of the power semiconductor device, the first length is larger than the second length. Exemplarily, all first parts have the same length, i.e. the first length, and all the second parts have the same length, i.e. the second length.

According to a further embodiment of the power semiconductor device, a maximum doping concentration of the first parts is higher than a maximum doping concentration of the second parts. Exemplarily, all first parts have the same maximum doping concentration and all the second parts have the same maximum doping concentration.

According to a further embodiment of the power semiconductor device, the at least one first doped region is arranged between the parts of the at least one second doped region along the main extension direction.

Exemplarily, the first doped region is arranged between side surfaces facing one another of directly neighbouring parts. For example, the first doped region can cover the side surfaces of directly neighbouring parts completely in lateral directions perpendicular to the main extension direction. Alternatively, the first doped region can cover the side surfaces of directly neighbouring first parts in regions in lateral directions perpendicular to the main extension direction. This is that the first doped region is arranged between end regions of directly neighbouring first parts and not in central regions of directly neighbouring first parts, where the second parts are arranged.

According to a further embodiment of the power semiconductor device, a distance of directly neighbouring parts is at least 0.1 μm and at most 1 μm. Exemplarily, the distance is defined between the side surfaces facing one another of directly neighbouring parts. In particular, the distance is defined between the side surfaces facing one another of directly neighbouring first parts. Alternatively or furthermore, the distance is defined between the side surfaces facing one another of directly neighbouring second parts.

According to a further embodiment of the power semiconductor device, when directly neighbouring parts are spaced apart from one another along the main extension direction, the at least one first doped region comprises first doped zones and a second doped zone, wherein the first doped zones are arranged between directly neighbouring parts of the at least one second doped region along the main extension direction. Exemplarily, the first doped zones are arranged between the side surfaces facing of directly neighbouring parts, in particular between the side surfaces of the end regions of the parts.

According to a further embodiment of the power semiconductor device, a maximum doping concentration of the first doped zones is lower than a maximum doping concentration of the second doped zones. Exemplary, the maximum doping concentration of the first doped zone is at least one or at least two orders of magnitude smaller than the maximum doping concentration of the second doped zone.

According to a further embodiment of the power semiconductor device, additional extensions extending perpendicular to the length of the parts are arranged at end regions of the parts. In particular, each part has two end regions opposite one another, wherein the end regions are located at an end of the parts along the lengths.

In particular, the parts and the additional extensions form the second doped region. For example, the parts and the additional extension are T-shaped in lateral directions in top view along the vertical direction.

According to a further embodiment of the power semiconductor device, the distance of directly neighbouring additional extensions is at least 0.1 μm and at most 1 μm. In particular, side surfaces facing one another of directly neighbouring additional extensions are spaced apart in lateral directions by the distance.

For example, the first doped zones are arranged between directly neighbouring additional extensions, in particular between side surfaces facing one another of directly neighbouring additional extensions. In this case, the second zone can be arranged between the side surfaces facing one another of directly neighbouring parts.

For example, the maximum doping concentration of the parts is the same than a maximum doping concentration of the additional extensions. Alternatively, the maximum doping concentration of the parts is higher than the maximum doping concentration of the additional extensions.

According to a further embodiment, the power semiconductor device comprises at least two well regions. Each well region comprises, for example, two first doped region between which the second doped region is arranged in lateral directions.

According to a further embodiment, the power semiconductor device comprises at least one intermediate region. Exemplarily, the intermediate region comprises the further first dopants, e.g. being n-type dopants. For example, a maximum doping concentration of the intermediate region is higher than the maximum doping concentration of the drift layer.

According to a further embodiment of the power semiconductor device, the at least two well regions and the at least one intermediate region are provided at the first side of the power semiconductor device.

According to a further embodiment of the power semiconductor device, the at least one intermediate region is provided between two of the at least two well regions, in particular in lateral directions.

The intermediate region is, exemplarily a junction field effect transistor, JFET, region or an electrons barrier region, which is advantageously introduced in the drift layer to increase locally the resistance of the source region.

According to a further embodiment, the power semiconductor device comprises a semiconductor body having a first main surface at the first side and a second main surface at a second side, wherein the semiconductor body comprises the drift layer, the at least one well region, the at least one first doped region and the at least one second doped region. The second side is opposite the first side in vertical direction. The semiconductor body can additionally comprise the intermediate region and/or a substrate layer.

According to a further embodiment, the power semiconductor device comprises a top metal layer arranged at the first main surface. For example, the top metal layer is provided on the source region, i.e. the first doped region and the second doped region at the first side. For example, the top metal layer is provided on the first main surface.

According to a further embodiment of the power semiconductor device, the top metal layer at least partially overlaps with the at least one first doped region and the at least one second doped region. Exemplarily, the top metal layer is in direct contact to the first doped region and the second doped region on their top surfaces.

For example, the end regions of the parts of the first doped region are free of the top metal layer. Exemplarily, the additional extensions are free of the top metal layer. This is, the end regions of the parts do not overlap in lateral directions with the top metal layer.

According to a further embodiment, the power semiconductor device comprises a substrate layer. Exemplarily, the substrate layer of the first conductivity type is arranged on the drift layer at the second side opposite the first side. For example, the maximum doping concentration of the drift layer is at least two orders of magnitude higher, exemplarily five times higher, than a maximum doping concentration of the drift layer.

According to a further embodiment, the power semiconductor device comprises a back metal layer arranged at the second main surface. For example, the back metal layer is provided on the second main surface of the drift layer at the second side. For example, the back metal layer covers the second main surface completely.

The top metal layer and/or the back metal layer comprises, for example, a metal or consists of a metal. For example, the top metal layer and/or the back metal layer is an electrode being externally contactable in an electrical conductive manner.

According to a further embodiment of the power semiconductor device, the substrate layer is arranged between the second electrode and the drift layer.

According to a further embodiment, the power semiconductor device comprises gate, which is arranged at the first main surface. In particular, the gate does not overlap with the source region in lateral directions. Exemplarily, the gate is arranged on the at least one intermediate region.

The gate comprises, exemplarily, a gate contact and a gate insulator. The gate contact comprises or consists of a metal. The gate insulator comprises, for example, an electrical insulating material, such as an electrical insulating oxide or high k-dielectrics. SiO₂ has a dielectric constant of 3.9 and “high k” dielectric materials are referred to as having a dielectric constant k>3.9.

For example, the gate contact is, at least in regions, externally contactable in an electrical conductive manner. Further, the gate contact is exemplarily embedded in the gate insulator. This is to say that the gate insulator covers all outer surfaces of the gate contact, except the region for external contacting.

A further embodiment relates to a method for producing a power semiconductor device, in particular, a power semiconductor device described herein above. Therefore, the features as described in connection with the method are also applicable for the power semiconductor device and vice versa.

According to an embodiment of the method, a drift layer of a first conductivity type is provided. In particular, the drift layer is an epitaxial semiconductor layer. For example, a base material of the drift layer is grown epitaxially. The base material is further doped with the first dopants.

According to the embodiment of the method, the at least one well region of a second conductivity type being different from the first conductivity type is produced at a first side. Exemplarily the well regions are produced within the drift layer, i.e. the base material, by a doping process. For example, the second dopants are introduced into the drift layer. Due to the introduction of the second dopants into the drift layer, the well regions are exemplarily generated.

According to the embodiment of the method, at least one first doped region of the first conductivity type and at least one second doped region of the second conductivity type are produced at the first side. Exemplarily the source region comprising the first doped region and the second doped region is produced within the drift layer by a further doping process.

For example, the source region is produced by introducing at least one of the further first dopants or the further second dopants into the drift layer. The term “at least one of the further first dopants or further second dopants are introduced” shall cover cases, in which either the further first dopants are introduced, or the further second dopants are introduced, or the further first dopants and the further second dopants are introduced.

The first dopants, the further first dopants, the second dopants and/or the further second dopants are, for example, incorporated within the drift layer, e.g. by an ion implantation process.

According to the embodiment of the method, a mask is used for generating the at least one first doped region such that an interface between the at least one first doped region and the at least one second doped region is structured. In particular, the mask is an implantation mask configured to confine an implantation region of the further first dopants.

According to a further embodiment of the method, a further mask is used for generating the at least one second doped region. In particular, the further mask is a further implantation mask configured to confine an implantation region of the further second dopants.

With such a method, no change in processing is required and advantageously, no extra masks are required to produce the structured interface between the first doped region and the second doped region—in comparison to producing a conventional SiC MISFET. To produce such structured interface, it is advantageously solely necessary to re-draw the implantation masks for the first dopants and the second dopants.

According to a further embodiment of the method, a self-aligned process is used for generating the at least one second doped region. With such a method the structured interface can be defined in particular simple and precise.

The accompanying Figures are included to provide a further understanding. In the Figures, elements of the same structure and/or functionality may be referenced by the same reference signs. It is to be understood that the embodiments shown in the Figures are illustrative representations and are not necessarily drawn to scale.

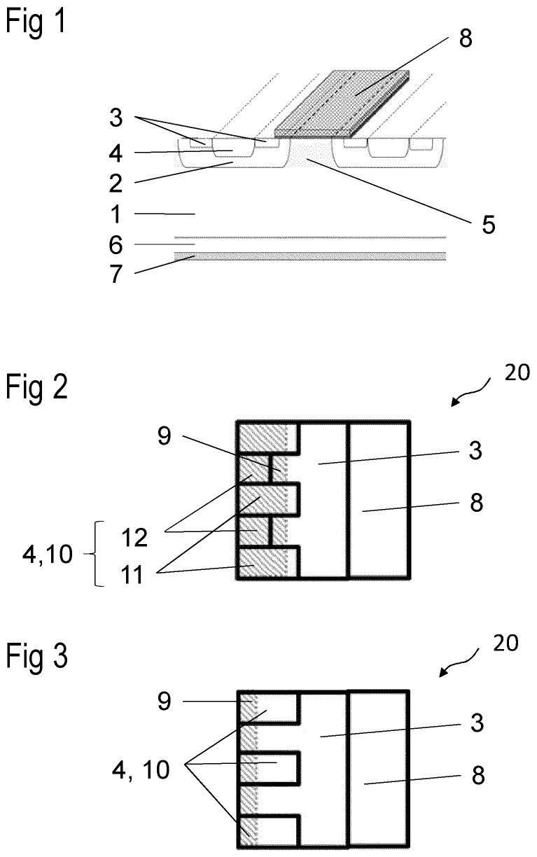

FIG. 1 exemplarily and schematically shows a schematic view of a power semiconductor device according to prior art.

FIGS. 2, 3 and 4 each schematically shows a top view of a power semiconductor device according to an exemplary embodiment.

FIGS. 5, 6, 7 and 8 each shows an exemplary diagram of simulated performance data, inter alia, of a power semiconductor device according to an exemplary embodiment.

The power semiconductor device according to FIG. 1 comprises a back metal layer 7, a substrate layer 6 and a drift layer 1 being stacked above one another in the order indicated. Adjacent layers are in direct contact to one another. Exemplarily, the drift layer 1 is an epitaxial drift layer 1. This is to say that the drift layer 1 is produced, e.g., by an epitaxial process. The drift layer 1 are of a first conductivity type.

A maximum doping concentration of the substrate layer 6 is higher than a maximum doping concentration of the drift layer 1. This is to say that the drift layer 1 is a low doped layer and the substrate layer 6 is a high doped layer.

The drift layer 1, and in particular the substrate layer 6, comprises a semiconductor material being formed of SiC.

For example, a highly doped collector layer of the second conductivity type can replace the substrate layer 6 being of the first conductivity type. In this case, the power semiconductor device 20 is an IGBT.

The power semiconductor device 20 further comprises two well regions 2 of a second conductivity type being different from the first conductivity type at a first side of the drift layer 1. The first side faces away from the back metal layer 7.

For example, the first conductivity type is an n-type conductivity. For example, the second conductivity type is a p-type conductivity.

The well regions 2 are produced, for example, within the drift layer 1 by a doping process. For example, second dopants are introduced in the drift layer 1 and thereby generating the well regions 2 up to a first depth.

The two well regions 2 are separated from one another in lateral directions. In other words, the two well regions 2 are arranged in the drift layer 1 having a distance to one another in lateral directions. Each of the two well regions 2 extends along a main extension direction. Further, the two main extension directions of the two well regions 2 are aligned parallel to one another.

An intermediate region 5 is arranged between the two well regions 2 at the first side, also extending along the main extension directions.

Each well region 2 comprises two first doped regions 3 of the first conductivity type and one second doped region 4 of the second conductivity type.

The two first doped regions 3 are separated from one another in lateral directions. In other words, the two first doped regions 3 are arranged in the respective well region 2 having a distance to one another in lateral directions and extending along the main extension direction of the respective well region 2. The second doped region 4 is arranged between the two first doped regions 3, also extending along the main extension direction of the respective well region 2. The first regions extend up to a second depth and the second region extends up to a third depth—in vertical direction, being perpendicular to a main extension plane of the power semiconductor device 20.

A top surface of the well regions 2, a top surface of the first doped regions 3, a top surface of the second doped regions 4 and a top surface of the intermediate region 5 are arranged within a common plane, i.e. a first main surface.

In addition, a gate 8 is arranged on the intermediate region 5 at the first side. The gate 8 covers the intermediate region 5 and the well region 2 and the gate 8 covers solely partially the first doped region 3, in particular their top surfaces. This is to say that the gate 8 overlaps with the intermediate region 5, the two well regions 2 and two of the first doped regions 3 of different well regions 2 in top view. The gate 8 comprises a gate contact and a gate insulator.

The power semiconductor device 20 according to the exemplary embodiment of FIG. 2 comprises an interface between the first doped region 3 and the second doped region 4, which is structured—in comparison to the power semiconductor device in FIG. 1. The second doped region 4 comprises a plurality of parts 10, wherein the parts comprise first parts 11 and second parts 12.

The parts 10, in particular the first parts 11 and the second parts 12, are arranged consecutively along the main extension direction next to one another. The first parts 11 and the second parts 12 are arranged in particular alternating along the main extension direction. Directly neighbouring parts 10 are in direct contact to one another along the main extension direction.

Each first part 11 has a first length perpendicular to the main extension direction and each second part 12 has a second length perpendicular to the main extension direction. The first length are larger than the second length. In particular, the first parts 11 protrude beyond the second parts 12 in direction perpendicular to the main extension direction. This is that end regions of the first parts 11 protrude beyond the second parts 12 in direction perpendicular to the main extension direction.

The first doped region 3 is arranged in lateral directions along the main extension direction between the end regions of directly neighbouring first parts 11 of the second doped region 4.

A top metal layer 9 is arranged on the parts 10 of the second doped region 4 as well as on the first doped region 3, in particular on the first main surface. The top metal layer 9 completely overlaps in lateral directions with the second parts 12 and partially overlaps with the first parts 11. End parts of the end regions of the first parts 11 are free of the top metal layer 9.

The top metal layer 9 partially overlaps in lateral directions with the first doped region 3. In particular, the top metal layer 9 is arranged on the first doped region 3 between the first parts 11 of the second doped region 4.

The power semiconductor device 20 according to the exemplary embodiment of FIG. 3 comprises in comparison to FIG. 2 parts 10 of the second doped region 4 having the same length. Directly neighbouring parts 10 are spaced apart from one another along the main extension direction. The first doped region 3 is arranged in lateral directions between directly neighbouring parts 10.

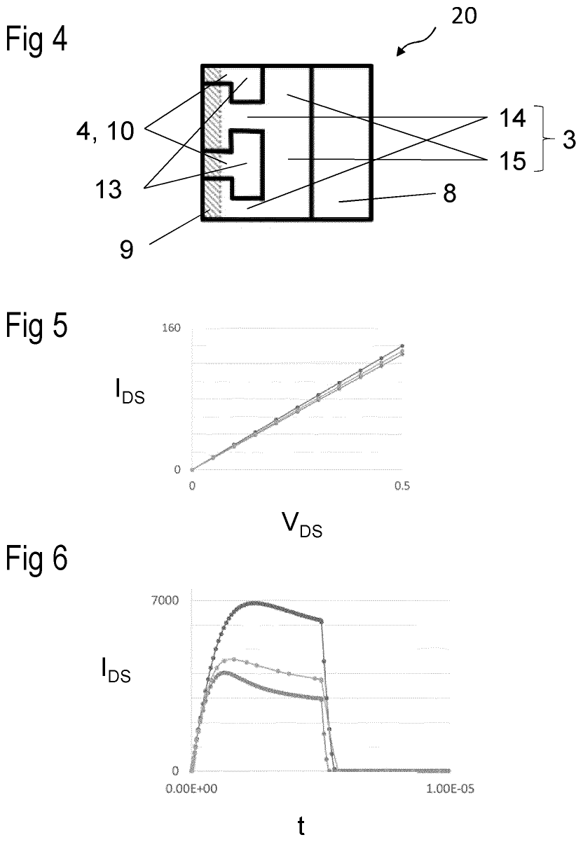

The power semiconductor device 20 according to the exemplary embodiment of FIG. 4 comprises in comparison to FIG. 3 parts 10, where additional extensions 13 are arranged at their end regions. The additional extensions 13 extend in particular along the main extension direction, such that they extend perpendicular to the parts 10.

The first doped region 3 is arranged in lateral directions between directly neighbouring parts 10, in particular also between directly neighbouring additional extensions 13.

In top view, the second doped region 4 with the parts 10 and the additional extension 13 are T-shaped in lateral directions.

Directly neighbouring additional extensions 13, in particular side surfaces of directly neighbouring additional extensions 13 facing one another, have exemplarily a distance of at least 0.1 μm and at most 1 μm.

The first doped region 3 comprises first doped zones 14 and a second doped zone 15, wherein the first doped zones 14 are arranged between directly neighbouring parts 10 of the one second doped region 4 along the main extension direction. This is that the first doped zones 14 are arranged between side surfaces facing one another of directly neighbouring additional extensions 13 facing one another in lateral directions.

A maximum doping concentration of the first doped zones 14 is lower than a maximum doping concentration of the second doped zone 15.

The second doped zone 15 extends in lateral directions from a side surface facing the intermediate region 5 up to the intermediate region 5.

A current, I_{DS}, in amperes, A/cm², is depicted on the y-axis of the diagram according to FIG. 5. Furthermore, a Drain-Source voltage, V_{DS}, in volt, V, is depicted on the x-axis. The uppermost I-V curve corresponds to a SiC MOSFET according to prior art without having a structured interface between a first and a second doped region 4.

Exemplarily, the uppermost I-V curve is computed dependent on the structure in FIG. 1.

The middle I-V curve corresponds to a power semiconductor device 20 being a SiC MISFET according to the exemplary embodiment of FIG. 4, where a distance between directly neighbouring additional extensions 13 is 0.3 μm. The bottommost I-V curve corresponds to a power semiconductor device 20 being a SiC MISFET according to the exemplary embodiment of FIG. 4, where a distance between directly neighbouring additional extensions 13 is 0.6 μm.

Exemplarily, the middle and the bottommost I-V curves are computed dependent on the structure in FIG. 4.

The values in the diagram in FIG. 5 are simulated with a Gate-Source Voltage V_{GS} of 15 V and a temperature of 300 K.

In FIG. 6, a current, I_{DS}, in amperes, A/cm², is depicted on the y-axis of the diagram. Furthermore, a time, t, in seconds, s, is depicted on the x-axis. The uppermost I-t curve corresponds to a SiC MOSFET according to prior art and the middle as well as the bottommost I-t curve to a Sic MISFET according to the exemplary embodiment of FIG. 4—analogously to the curves shown in FIG. 5.

The values in the diagram in FIG. 6 are simulated with a Gate-Source Voltage V_{GS} of 15 V and a Drain-Source Voltage V_{DS} of 600 V.

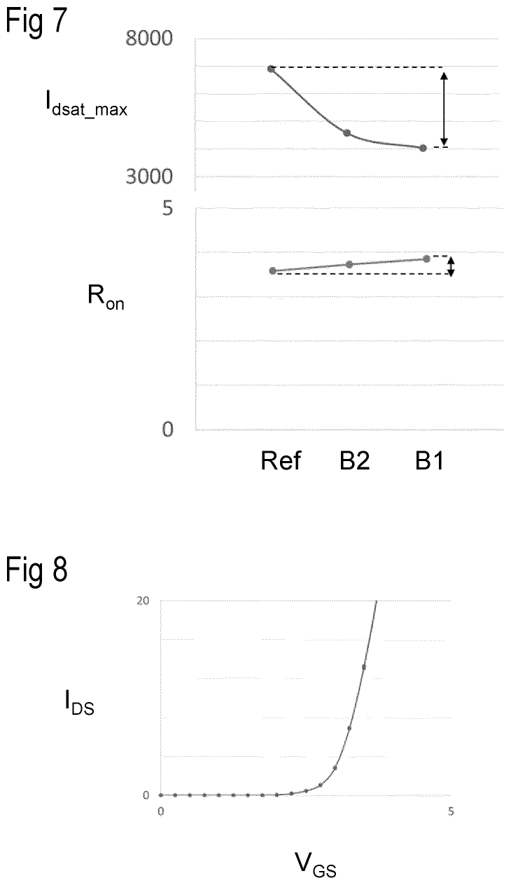

FIG. 7 shows a summary of the result presented in the FIGS. 5 and 6. The B1 design corresponds to the power semiconductor device 20 of FIG. 4 with the distance of 0.3 μm. B1 offers a significant 42% reduction in I_{Dsat_max} in A/cm², while the specific Rₒₙ value in mΩcm² only sees a modest increase of 7%. This, in turn, will result in longer SCWT values and, hence, improved device ruggedness.

The B2 design corresponds to the power semiconductor device 20 of FIG. 4 with the distance of 0.6 μm. The Ref design corresponds to a reference power semiconductor device 20 according to FIG. 1—i.e. being prior art.

In the diagram in FIG. 8, a transfer characteristics of a reference SiC MOSFET, Ref, and one which uses the B1 design are shown. The values in the diagram in FIG. 8 are simulated with a Drain-Source Voltage V_{DS} of 1 V and a temperature of 300 K. Substantially, no change can be observed.

### REFERENCE SIGNS

1 drift layer
2 well region
3 first doped region
4 second doped region
5 intermediate region
6 substrate layer
7 back metal layer
8 gate
9 top metal layer
10 parts
11 first part
12 second part
13 additional extension
14 first doped zone
15 second doped zone
20 power semiconductor device

1. A power semiconductor device, comprising
a drift layer of a first conductivity type,
at least one well region of a second conductivity type being different from the first conductivity type, and
at least one first doped region of the first conductivity type and at least one second doped region of the second conductivity type, wherein
the at least one well region, the at least one first doped region and the at least one second doped region are provided at a first side of the power semiconductor device,
the at least one first doped region and the at least one second doped region are spaced apart from the drift layer by the at least one well region,
an interface between the at least one first doped region and the at least one second doped region is structured being non uniform in a main extension direction of the at least one well region,
the at least one second doped region comprises a plurality of parts,
the plurality of parts comprises first parts and second parts being arranged consecutively alternating along the main extension direction, and
a maximum doping concentration of the first parts is higher than a maximum doping concentration of the second parts
the plurality of parts are arranged consecutively along a main extension direction next to one another, and
each of the plurality of parts have a length perpendicular to the main extension direction
directly neighbouring first parts and second parts are in direct contact to one another along the main extension direction,
each first part has a first length perpendicular to the main extension direction and each second part has a second length perpendicular to the main extension direction, and
the first length is larger than the second length.

2. The power semiconductor device according to claim 1, further comprising
at least two well regions, and
at least one intermediate region, wherein
the at least two well regions and the at least one intermediate region are provided at the first side of the power semiconductor device,
the at least one intermediate region is provided between two of the at least two well regions.

3. The power semiconductor device according to claim 1, further comprising
a semiconductor body having a first main surface at the first side and a second main surface at a second side, wherein
the semiconductor body comprises the drift layer, the at least one well region, the at least one first doped region and the at least one second doped region.

4. The power semiconductor device according to claim 3, further comprising
a top metal layer arranged at the first main surface, wherein
the top metal layer at least partially overlaps with the at least one first doped region and the at least one second doped region.

5. The power semiconductor device according to claim 3, further comprising
a substrate layer, and
a back metal layer arranged at the second main surface, wherein,
the substrate layer is arranged between the back metal layer arranged and the drift layer.

6. The power semiconductor device according to claim 3, further comprising a gate, which is arranged at the first main surface.

7. A method for producing a power semiconductor device, comprising:
proving a drift layer of a first conductivity type,
producing at least one well region of a second conductivity type being different from the first conductivity type at a first side, and
producing at least one first doped region of the first conductivity type and at least one second doped region of the second conductivity type at the first side, wherein,
a mask is used for generating the at least one first doped region, such that an interface between the at least one first doped region and the at least one second doped region is structured,
the at least one second doped region comprises a plurality of parts,
the plurality of parts comprises first parts and second parts being arranged consecutively alternating along the main extension direction, and
a maximum doping concentration of the first parts is higher than a maximum doping concentration of the second parts,
the plurality of parts are arranged consecutively along a main extension direction next to one another, and
each of the plurality of parts have a length perpendicular to the main extension direction
directly neighbouring first parts and second parts are in direct contact to one another along the main extension direction,
each first part has a first length perpendicular to the main extension direction and each second part has a second length perpendicular to the main extension direction, and
the first length is larger than the second length.

8. A method for producing a power semiconductor device according to claim 7, wherein
a further mask is used for generating the at least one second doped region, or
a self-aligned process is used for generating the at least one second doped region such that the interface between the at least one first doped region and the at least one second doped region is structured.

9-15. (canceled)
